(19) United States
(12) Patent Application Publication
(10) Pub. No.: US 2012/0159817 A1
(43) Pub. Date: Jun. 28, 2012

(54) Display Apparatus and Outdoor Displaying System

(75) Inventor: Masaya NAKAMICHI, Moriguchi City (JP)

(73) Assignee: Sanyo Electric Co., Ltd., Moriguchi City (JP)

(21) Appl. No.: 13/309,094

(22) Filed: Dec. 1, 2011

(30) Foreign Application Priority Data
Dec. 24, 2010 (JP) 2010-287021

(51) Int. Cl. H05K 5/02; G09F 9/00

(52) U.S. Cl. 40/448; 454/184

(57) ABSTRACT

The display apparatus has a display portion, an inlet, an outlet, a fan portion which generates the air flow from the inlet to the outlet along the display portion, a exhaust duct having an opening in the bottom side and leading the air emitted from the outlet to the opening, and a inhale duct having an opening in the bottom side and leading the air entered from the opening to the inlet.

### CROSS-REFERENCE TO RELATED APPLICATIONS

This application is based on Japanese Patent Application No. 2010-287021 filed on Dec. 24, 2010, the contents of which are hereby incorporated by reference.

### BACKGROUND OF THE INVENTION

1. Field of the Invention

The present invention relates to a display apparatus which displays image, and outdoor displaying system equipping said apparatus.

2. Description of the Related Art

In recent years, large-sized display apparatuses called “digital signage” which are deployed outdoors, which display information such as advertising information are emerging.

For example, when it is installed outdoors, the temperature inside the display may become high in the daytime of midsummer etc, and this may hamper the performance of the liquid crystal panel. Thus, one idea is to use fan and generate the air-flow inside the cabinet. However, raindrop or dust may go inside the cabinet from the air inlet or the outlet.

### SUMMARY OF THE INVENTION

According to one aspect of the display apparatus of the present invention, the apparatus comprises a display portion; an inlet; an outlet; a fan portion which generates the air flow from the inlet to the outlet along the display portion, and a exhaust duct having an opening in the bottom side and leading the air emitted from the outlet to the opening. According to an another aspect of the display apparatus of the present invention, the apparatus comprises a display portion; an inlet; an outlet; a fan portion which generates the air flow from the inlet to the outlet along the display portion, and a inhale duct having an opening in the bottom side and leading the air entered from the opening to the inlet.

### DESCRIPTION OF THE DRAWINGS

FIG. 1 is a front perspective view of the outdoor display system 9.

FIG. 2 is a rear perspective view of the outdoor display system 9.

FIG. 3 is a side view of the outdoor display system 9.

FIG. 4 is a front perspective view of the display 4.

FIG. 5 is a horizontal sectional view of the display 4.

FIG. 6 is a vertical sectional view of the display 4.

FIG. 7 is a schematic diagram of the battery unit 7.

FIG. 8 is a vertical sectional view of the battery unit 7.

FIG. 9 is a front perspective view of the outdoor display system 90.

### DESCRIPTION OF THE PREFERRED EMBODIMENTS

### First Embodiment

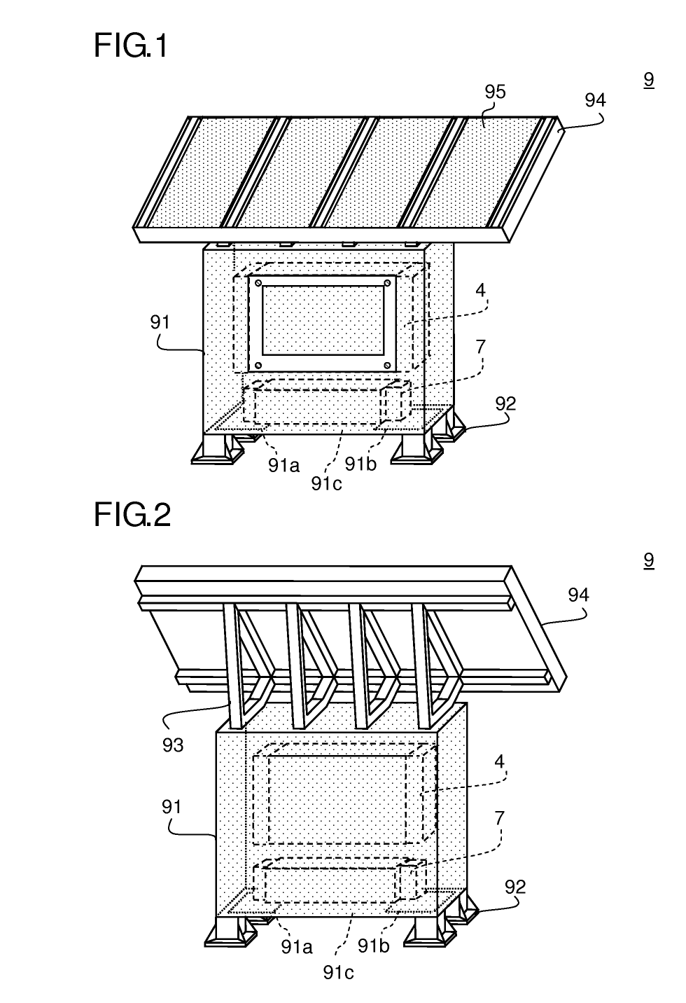

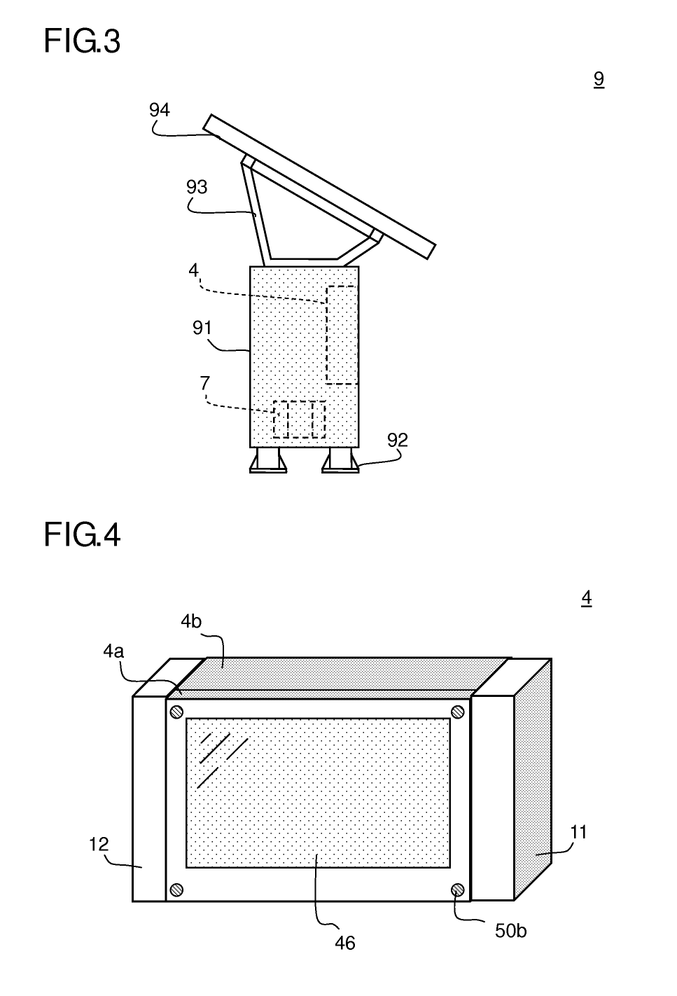

FIGS. 1, 2 and 3 are the outline views of the outdoor display system 9 of the present invention. FIG. 1 is its front perspective view, FIG. 2 is its side view, and FIG. 3 is its rear perspective view.

As shown in these figures, the outdoor display system 9 has a case 91 which stores a display 4, a battery unit 7.

Under the case 91, leg portions 92 for installing the system 9 on the ground are formed. In the lower surface 91c of the case 91, the openings 91a and 91b are formed. By these openings, the inside and the outside are the communicated so that the air can flow their between.

The display 4 displays information or image. The display has an antenna which receives a wireless signal (WiMAX and IEEE802.11b/g etc.) from an external server (ASP server, personal computer, etc.), or a signal from a broadcasting station. The display further demodulates the signal received by the antenna, extracts the MPEG2-TS format signal and separates the extracted signal into the image signal and the audio signal. Then decoding is performed before outputting signals from the LCD panel 44 or a speaker.

Moreover, the MPEG 2-TS format signal may be stored temporality in the internal memory (or HDD drive inside the display 4), and the content of the signal may be displayed on the LCD panel 44 triggered by operation of a user or a predetermined time schedule.

In the front side or the rear side of the front glass 13 which is in front of the LCD panel 44, a touch panel 46 comprising an electric capacity type touch sensor sheet is equipped.

On the respective side of the display 4, an intake duct 11 and an exhaust duct 12 are formed. Under the duct 12, an opening 91a is formed. Under the duct 11, an opening 91b is formed.

Above the case 91, a solar cell 95 is installed. Referring to FIG. 2, a supporting portion 93 is arranged on the upper surface of the case 91. The portion 93 supports a stand 94. On the stand 94, solar cell 1 which receives sunlight is installed. The angle of the stand 94 is set so that it conforms with the incidence angle of the sunlight.

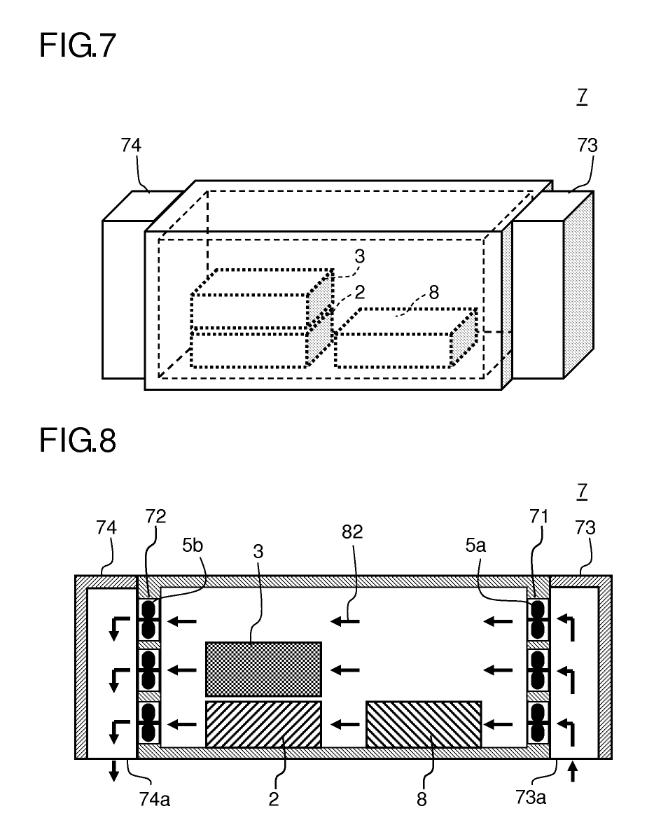

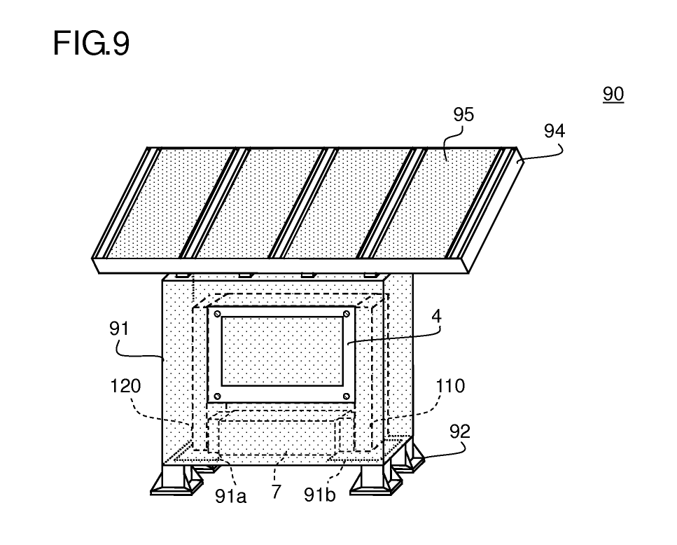

Inside the battery unit 7, a battery 2, a controller 3, and an inverter 8 are stored in the case (see FIG. 7). The battery 2 is, for example, a lithium ion battery. The controller 3 controls so that the electric power generated by the solar cell 95 is supplied to the display 4 or the battery 2. Basically, the controller 3 supplies the most of the power from the solar cell 95 to the display 4, and supplies the remainder to the battery 2. However, when the solar cell 95 does not generate power (such as nighttime or cloudy days), the controller 3 controls so that the power is supplied to the display 4 from the battery 2.

Referring to FIG. 4, a casing of the display 4 comprises a front cabinet 4a and a back cabinet 4b. Inside these cabinets, a LCD panel and an electric circuit and other components are stored. On the right side of the cabinet, an intake duct 11 is attached. On the left side of the cabinet, the exhaust duct 12 is attached.

FIG. 5 is a horizontal sectional view of the display 4. Referring to this figure, the LCD panel 44 is formed inside the back cabinet 4b. On the rear side of the panel 44, a back light 45 is formed. To the front cabinet 4a, a transparent front glass 13 is inserted so as to face the panel 44. On the front surface of the glass 13, a touch panel 46 is attached. The touch panel 46 may be attached on the rear side of the glass 13 (i.e. on the side facing the panel 44).

In the daytime of midsummer, the temperature inside the display may become high when it is installed outdoors, and this may hamper the performance of the display apparatus. In order to prevent the malfunction of touch panel 46 derived by the temperature condition, it is necessary to control the temperature of the panel 46.

Thereby, the display 4 has fan on its both side and cools the LCD panel 44 and the touch panel 46 by making an air-flow in the front side of the LCD panel 44.

Referring to FIG. 5 again, between the LCD panel 44 and the front glass 13, a space 81 is set. Thereby, the ventilation from the inlet 14 to the outlet 14 is achieved.

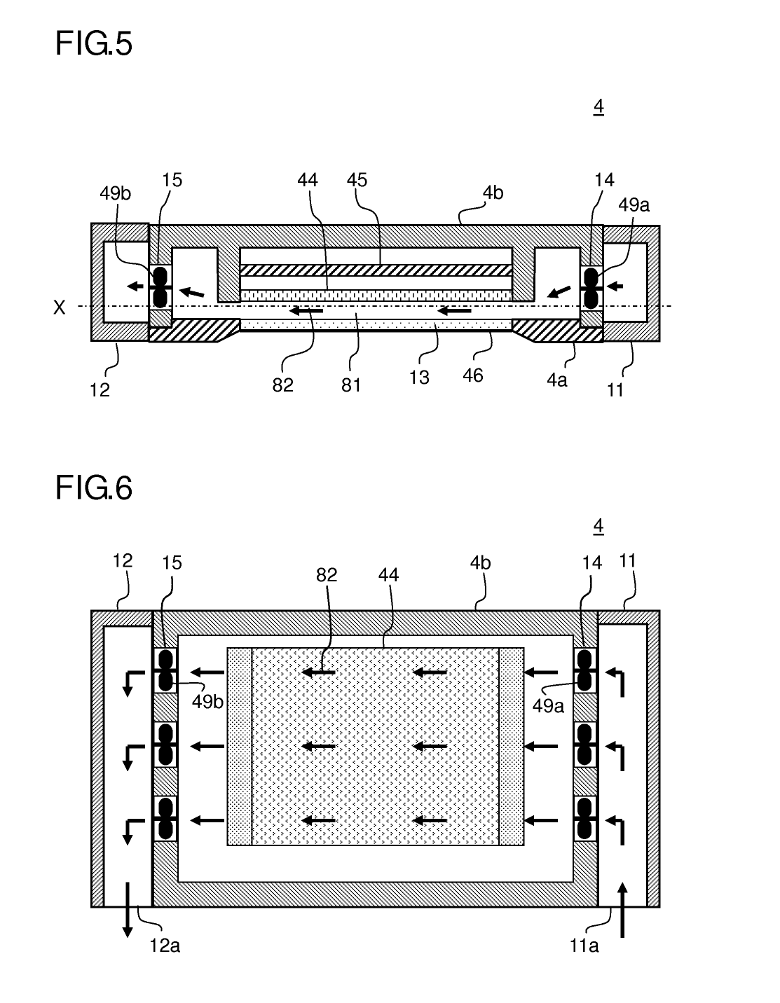

FIG. 6 is a vertical sectional view of the display 4. As shown in this figure, on the right-hand side of the display 4, three inlets 14 are located in a vertical direction. On the left-hand side of the display 4, three outlets 15 are located in a vertical direction as well.

In each of the inlets 14, intake fans 49a are arranged. In each of the outlet 15, exhaust fans 49b are arranged. In the inlet 14 and the outlet 15, a filter for preventing dust intruding into space 81 may be arranged.

In the outside of the inlet 14, the intake duct 11 is attached. The duct 11 is arranged vertically along the side-face of the back cabinet 4b so as to cover these three inlets 14.

On the undersurface of the intake duct 11, the inlet 11a is arranged. Generally, the rain falls downward, but the opening of the duct 11 (inlet 11a) is arranged downward. Thereby, it can prevent raindrops intruding into the duct 11.

In the outside of the outlet 15, the exhaust duct 12 is attached. The duct 12 is arranged vertically along the side-face of the back cabinet 4b so as to cover these three outlets 15.

On the undersurface of the exhaust duct 12, the outlet 12a is arranged. Since the opening of the duct 12 (outlet 12a) is arranged downward, it can prevent raindrops intruding into the duct 12.

These fans are driven when the illumination detected by the illumination sensor 50b (see FIG. 4) arranged in front side of the display 4 (i.e. in four corners of the LCD panel 44) exceeds a predetermined value. When the detected illumination is high, it means that strong sunlight is irradiating the panel 44, and thus the temperature of the panel 44 may rise. Therefore, in such case, the fan is driven to prevent the panel 44 from heated.

Further, the temperature sensor may be arranged on the display 4 as well. The fans may be driven when the temperature detected by this sensor exceeds a predetermined value.

FIG. 7 is a schematic diagram of the battery unit 7. In the unit 7, the battery 2, the controller 3, and the inverter 8 are stored in a case.

FIG. 8 is a vertical sectional view of the unit 7. Referring to the figure, in the right side portion of the unit 7, three inlets 71 are set vertically. In the left side portion of the unit 7, three outlets 72 are set vertically.

In each of the inlets 71, the intake fan 5a is set. In each of the outlets 72, the exhaust fan 5b is set. When these fans are driven, air-flow between the inlet 71 and outlet 72 is generated.

In this embodiment, the inverter 8, in which the temperature tends to become high, is arranged in the inlet 71 side so that the inverter 8 is cooled with high priority. The battery unit 7 also has an intake duct 73 and an exhaust duct 74.

### Second Embodiment

FIG. 10 is a front perspective view of the outdoor display system 90 of the present embodiment. It differs from the system 9 that the intake duct 110 and the exhaust duct 120 are further stretching down from the side surface of the display 4. This means that the lower portion of the ducts 110 and 120 are arranged also in the side of the battery unit 7, the inlet or the outlet of these ducts are arranged above the opening 91a or 91b. Thereby, inside of the display 4 can be performed much efficiently.

What is claimed is:

1. A display apparatus comprising:
a display portion;
an inlet;
an outlet;
a fan portion which generates the air flow from the inlet to the outlet along the display portion, and
a exhaust duct having an opening in the bottom side and leading the air emitted from the outlet to the opening.

2. A display apparatus comprising:
a display portion;
an inlet;
an outlet;
a fan portion which generates the air flow from the inlet to the outlet along the display portion, and
a inhale duct having an opening in the bottom side and leading the air entered from the opening to the inlet.

3. A display apparatus comprising:
a display portion;
an inlet;
an outlet;
a transparent protecting component arranged in the front side of the display portion and being separated from the display portion;
a fan portion which generates the air flow from the inlet to the outlet between the display portion and the transparent protecting component;
an exhaust duct arranged vertically in one side of the display portion, the duct leading the air emitted from the outlet to the outside, and
an inhale duct arranged vertically in the other side of the display portion, the duct leading the outside air to the inlet.

4. An outdoor display system, comprising:
a solar cell;
a display apparatus as claimed in claim 1, and
a control unit which converts an electric power generated by the solar cell, and supplies to the display, wherein
one of the exhaust duct or the inhale duct is arranged so that the duct stretches along the control unit.

5. An outdoor display system, comprising:
a solar cell;
a display apparatus as claimed in claim 2, and
a control unit which converts an electric power generated by the solar cell, and supplies to the display, wherein
one of the exhaust duct or the inhale duct is arranged so that the duct stretches along the control unit.
